(19) United States
(12) Patent Application Publication
(10) Pub. No.: US 2025/0017004 A1
(43) Pub. Date: Jan. 9, 2025

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: CHUN-YAO KO, HSINCHU CITY (TW); LIANG-TAI KUO, HSINCHU COUNTY (TW); SHIH-HSIEN CHEN, HSINCHU COUNTY (TW); YINGKIT FELIX TSUI, CUPERTINO, CA (US)

(21) Appl. No.: 18/347,542

(22) Filed: Jul. 5, 2023

(51) Int. Cl. H10B 41/10; H01L 29/423; H01L 29/788; H10B 41/70

(52) U.S. Cl. CPC H10B 41/10; H01L 28/92; H01L 29/42324; H01L 29/788; H10B 41/70

(57) ABSTRACT

A semiconductor device and a method of manufacturing the same are provided. The semiconductor device includes a substrate, a transistor, and a capacitor. The transistor includes a gate electrode disposed on the substrate. The capacitor is electrically connected to the transistor and includes a capacitor dielectric and a capacitor electrode. The capacitor dielectric and the capacitor electrode are stacked over the gate electrode of the transistor.

### BACKGROUND

The present invention relates to a semiconductor device, and more particularly to a semiconductor device with integrated circuit (IC) design.

In recent years, high density multiple time programmable (HDMTP) memory cells are increasingly used for manufacturing Non-Volatile Memories (NVM). In particular, a HDMTP memory cell having a new structure has various advantages over conventional NVM devices. Such advantages include, for example, compatible fabrication current complementary-metal-oxide-semiconductor (CMOS) technologies or other technologies, smaller layout area, high integration density, and others.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1A illustrates a schematic view of a layout of a semiconductor device, in accordance with some embodiments of the present disclosure.

FIG. 1B illustrates a schematic view of a semiconductor device according to the layout of FIG. 1A, in accordance with some embodiments of the present disclosure.

FIG. 1C illustrates a cross-sectional view of a portion of the semiconductor device shown in FIG. 1B along the line A-A′ and another portion of the semiconductor device shown in FIG. 1B along the line B-B′, in accordance with some embodiments of the present disclosure.

FIG. 2 illustrates a cross-sectional view of a semiconductor device, in accordance with some embodiments of the present disclosure.

FIG. 3 illustrates a cross-sectional view of a semiconductor device, in accordance with some embodiments of the present disclosure.

FIGS. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, FIG. 4M, FIG. 4N, FIG. 4O, FIG. 4P, and FIG. 4Q illustrate various stages of manufacturing a semiconductor device, in accordance with some embodiments of the present disclosure.

FIG. 5 is a flow chart illustrating a method for manufacturing a semiconductor device, in accordance with various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially.” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

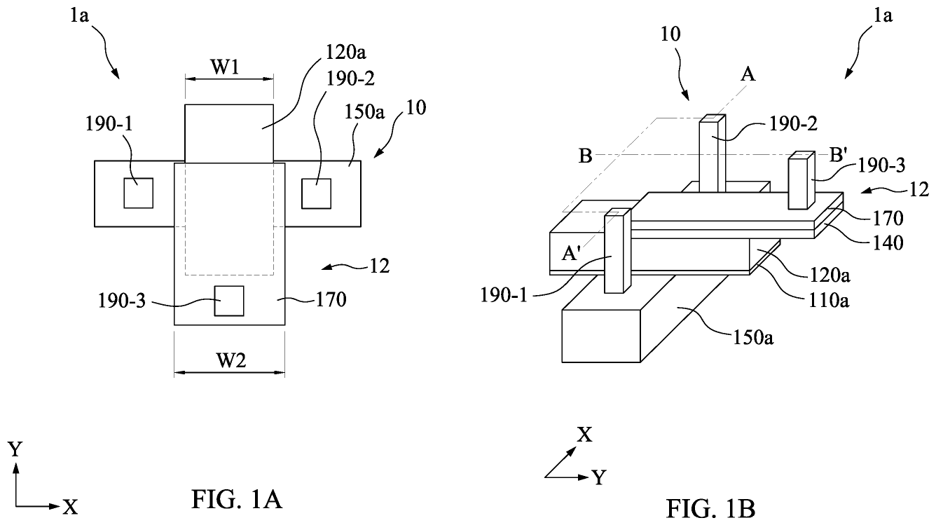

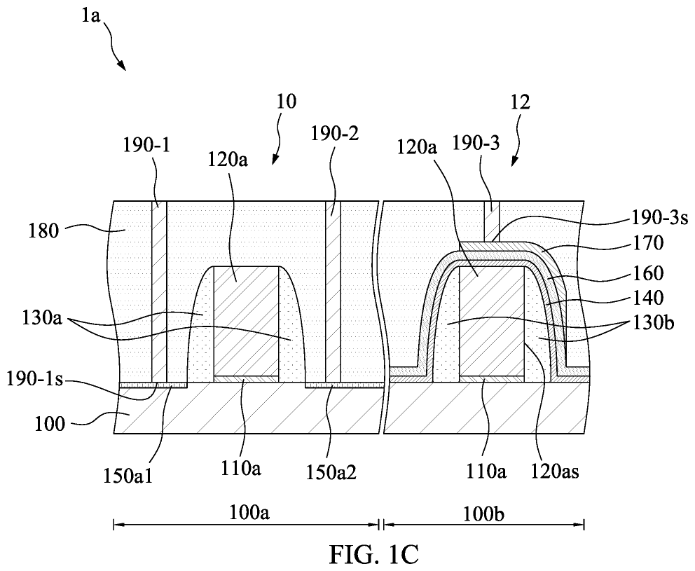

FIG. 1A illustrates a schematic view of a layout of a semiconductor device 1a, in accordance with some embodiments of the present disclosure.

The semiconductor device 1a includes a memory cell. In some embodiments, the semiconductor device 1a includes a transistor 10 and a capacitor 12. In some embodiments, the transistor 10 includes an active region 150a, a semiconductor layer 120a, and contacts 190-1 and 190-2. In some embodiments, the active region 150a refers to the region that is used to perform operations of the transistor 10. In some embodiments, the semiconductor layer 120a functions as a gate electrode of the transistor 10.

The capacitor 12 includes the semiconductor layer 120a, a capacitor dielectric (not shown in FIG. 1A), a metal structure 170, and a capacitor contact 190-3. In some embodiments, the semiconductor layer 120a functions as a capacitor electrode of the capacitor 12. In some embodiments, the metal structure 170 functions as a capacitor electrode of the capacitor 12.

In some embodiments, the active region 150a extends along an X-axis. In some embodiments, the semiconductor layer 120a extends along a Y-axis. In some embodiments, the semiconductor layer 120a is formed on the active region 150a. In some embodiments, the semiconductor layer 120a overlaps the active region 150a. In some embodiments, the contacts 190-1 and 190-2 (or transistor contacts) are formed on the active region 150a. In some embodiments, the semiconductor layer 120a has a width W1 along the X-axis. In some embodiments, the X-axis is orthogonal to the Y-axis. The terms “overlap” and “overlapping” in this disclosure are used to describe that two elements and/or features are at least partially vertically aligned.

In some embodiments, the metal structure 170 extends along the Y-axis. In some embodiments, the metal structure 170 has a width W2 along the X-axis. In some embodiments, the width W2 of the metal structure 170 exceeds the width W1 of the semiconductor layer 120a along the X-axis. In some embodiments, the capacitor contact 190-3 is formed on the metal structure 170. In some embodiments, the capacitor contact 190-3 is electrically connected to the metal structure 170.

It should be noted that some elements of the semiconductor device 1a are not shown in FIG. 1A for clarity. The numbers of the active regions, the gates, and the metal features are given for illustrative purposes. Various numbers of the active regions, the gates, and the conductive features and other features are within the contemplated scope of the present disclosure. The terms “comprise” or “comprising,” “include” or “including,” “have” or “having,” and the like used in this application are to be understood to be open-ended, i.e., to mean including but not limited to. Accordingly, various elements and/or structures, which are not shown in FIG. 1A and formed in the semiconductor device 1a, are within the contemplated scope of the present disclosure.

FIG. 1B illustrates a schematic view of a semiconductor device 1a according to the layout of FIG. 1A, in accordance with some embodiments of the present disclosure.

In some embodiments, the transistor 10 includes a gate dielectric 110a disposed on the active region 150a. The gate dielectric 110a is located at a first horizontal level higher than the horizontal level of the active region 150a. In some embodiments, the gate dielectric 110a overlaps the active region 150a. In some embodiments, the gate dielectric 110a extends along the Y-axis. In some embodiments, the semiconductor layer 120a is disposed on the gate dielectric 110a. The semiconductor layer 120a is located at a second horizontal level higher than the first horizontal level of the gate dielectric 110a. In some embodiments, the semiconductor layer 120a overlaps the gate dielectric 110a. In some embodiments, the gate dielectric 110a is disposed between the active region 150a and the semiconductor layer 120a. In some embodiments, the line B-B′ is along the Y-axis.

The contacts 190-1 and 190-2 are electrically connected to the active region 150a. In some embodiments, the contacts 190-1 and 190-2 can be spaced apart from each other. The contacts 190-1 and 190-2 can be located, for example, at two opposite sides of the semiconductor layer 120a. The semiconductor layer 120a is disposed between the contacts 190-1 and 190-2 along the X-axis. In some embodiments, the contacts 190-1 and 190-2 are arranged along the X-axis.

In some embodiments, the capacitor 12 includes an insulation layer 140 between the semiconductor layer 120a and the metal structure 170. In some embodiments, the insulation layer 140 is also referred to as a capacitor dielectric.

In some embodiments, the capacitor 12 is electrically connected to the transistor 10 because the semiconductor layer 120a functions as both the gate electrode of the transistor and the capacitor electrode of the capacitor. In some embodiments, the insulation layer 140 is disposed on the semiconductor layer 120a. The insulation layer 140 is located at a third horizontal level higher than the second horizontal level of the semiconductor layer 120a. In some embodiments, the insulation layer 140 overlaps the semiconductor layer 120a. In some embodiments, the metal structure 170 is disposed on the insulation layer 140. The metal structure 170 is located at a fourth horizontal level higher than the third horizontal level of the insulation layer 140. In some embodiments, the metal structure 170 overlaps the insulation layer 140. In some embodiments, the metal structure 170 vertically overlaps the semiconductor layer 120a of the transistor 10. In some embodiments, the insulation layer 140 and the metal structure 170 are stacked over the semiconductor layer 120a.

In some embodiments, the capacitor contact 190-3 is electrically connected to the metal structure 170. In some embodiments, the capacitor contact 190-3 is in contact with the metal structure 170. The capacitor contact 190-3 is located at a fifth horizontal level higher than the fourth horizontal level of the metal structure 170. In some embodiments, the insulation layer 140 extends along the Y-axis. In some embodiments, the capacitor contact 190-3 is disposed between the contacts 190-1 and 190-2 along the X-axis.

In a comparative semiconductor device, the capacitor contact is disposed on an active region, which occupies an additional area of a substrate. By using the layout of the semiconductor device 1a shown in FIG. 1A and the structure of the semiconductor device 1a shown in FIG. 1B, the layout area of the semiconductor device 1a can be significantly reduced when compared to the layout area of a conventional semiconductor device since an active region for capacitor contact is omitted. For example, when performing a layout of an 8×8 array of HDMTP memory cells, the layout area of the semiconductor device 1a can be reduced to 63% of that of a conventional semiconductor device. Since the layout area of the semiconductor device 1a can be reduced, more memory cells can be manufactured on a die. Additionally, the program and erase operation mechanisms of the conventional semiconductor device are still compatible in the semiconductor device 1a shown in FIGS. 1A and 1B. Further, in some embodiments, the semiconductor layer 120a may be replaced by other conductive materials, such as metal, alloy, or other suitable materials.

FIG. 1C illustrates a cross-sectional view of a portion of the semiconductor device 1a shown in FIG. 1B along the line A-A′ and another portion of the semiconductor device 1a shown in FIG. 1B along the line B-B′, in accordance with some embodiments of the present disclosure.

Referring to FIG. 1C, the semiconductor device 1a includes the transistor 10 and the capacitor 12. In some embodiments, the cross-sectional view on the left side of the break line illustrates a cross-sectional view of the transistor 10 shown in FIG. 1B along the line A-A′. The cross-sectional view on the right side of the break line illustrates a cross-sectional view of the capacitor 12 shown in FIG. 1B along the line B-B′. The semiconductor device 1a includes a substrate 100. The substrate 100 includes a region 100a and a region 100b. A transistor, such as the transistor 10, is disposed within or on the region 100a. A capacitor, such as the capacitor 12, is disposed within or on the region 100b.

The substrate 100 is a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material disposed on an insulator layer. The insulator layer may be, for example, a buried oxide (BOX) layer, a silicon oxide layer, or the like. Other substrates, such as a multilayered or gradient substrate may also be used. In some embodiments, the semiconductor material of the substrate 100 may include silicon, germanium, a compound semiconductor including silicon carbide, gallium arsenic, gallium phosphide, indium phosphide, indium arsenide, and/or indium antimonide, an alloy semiconductor including SiGe, GaAsP, AlinAs, AlGaAs, GalnAs, GaInP, and/or GaInAsP, or combinations thereof. The substrate 100 may include a plurality of regions (not shown) for forming p-type devices and/or n-type devices, such as PMOS and/or transistors, e.g., p-type FinFETs and/or n-type FinFETs. The active region 150a, as shown in FIG. 1A and FIG. 1B, can be a region, doped with dopants, within the substrate 100.

In some embodiments, a gate dielectric 110a is disposed on the regions 100a and 100b of the substrate 100. The gate dielectric 110a may be a single layer or multiple layers. In some embodiments, the gate dielectric may include silicon oxide (SiOₓ), silicon nitride (SiₓN_{y}), silicon oxynitride (SiON), or a combination thereof. In some embodiments, the gate dielectric may include dielectric material(s), such as high-k dielectric material. The high-k dielectric material may have a dielectric constant (k value) greater than 4. The high-k material may include hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. Other suitable materials are within the contemplated scope of the disclosure.

In some embodiments, a semiconductor layer 120a is disposed on the gate dielectric 110a. In some embodiments, the semiconductor layer 120a is electrically floating. The semiconductor layer 120a may include polysilicon, silicon-germanium, or other suitable materials. In some embodiments, the semiconductor layer 120a can be replaced by a metallic layer, which include Mo, Cu, W, Ti, Ta, TiN, TaN, NiSi, CoSi, or other suitable conductive materials.

In some embodiments, a spacer 130a is disposed on the region 100a. In some embodiments, a spacer 130b is disposed on the region 100b. In some embodiments, the gate dielectric 110a and the semiconductor layer 120a are disposed between two portions of the spacer 130a. In some embodiments, the gate dielectric 110a and the semiconductor layer 120a are in contact with the spacer 130a. In some embodiments, the gate dielectric 110a and the semiconductor layer 120a are disposed between two sides of the spacer 130b. In some embodiments, the gate dielectric 110a and the semiconductor layer 120a are in contact with the spacer 130b.

In some embodiments, the spacer 130a is disposed on two sidewalls of the semiconductor layer 120a of the transistor 10 along a first orientation such as the X-axis as shown in FIG. 1B. In some embodiments, the spacer 130b is disposed on two sides of the semiconductor layer 120a along a second orientation such as the Y-axis as shown in FIG. 1B. The spacers 130a and 130b include a single layer structure or a multilayer structure. In some embodiments, the spacers 130a and 130b include SiO₂, SiN, SiCN, SiOCN, SiC, SiOC, SiON, or the like, or combinations thereof. In some embodiments, the spacers 130a and 130b are the same material.

In some embodiments, an insulation layer 140 is disposed on the region 100b, the semiconductor layer 120a, and the spacer 130b. In some embodiments, the insulation layer 140 is in contact with the region 100b, the semiconductor layer 120a, and the spacer 130b.

In some embodiments, salicide structures 150al and 150a2 (or salicide layers) are disposed in the region 100a. In some embodiments, the salicide structures 150al and 150a2 are spaced apart from each other. In some embodiments, the salicide structures 150al and 150a2 are located, for example, at two opposite sides of the semiconductor layer 120a. The salicide structures 150a1 and 150a2 are located in a region of the substrate 100 corresponding to source/drain regions. The salicide structures 150al and 150a2 are also referred to as silicide structures.

In some embodiments, an etch stop layer 160 is conformally disposed on the insulation layer 140. In some embodiments, the etch stop layer 160 is disposed on the region 100b. In some embodiments, the etch stop layer 160 is in contact with the insulation layer 140. In some embodiments, the etch stop layer 160 includes silicon nitride, silicon dioxide, silicon carbide, silicon carbonitride, and the like. The material of the etch stop layer 160 is different from that of the insulation layer 140.

In some embodiments, the metal structure 170 is disposed on a portion of the etch stop layer 160. In some embodiments, the metal structure 170 is disposed on a portion of the insulation layer 140. In some embodiments, the metal structure 170 is in contact with the etch stop layer 160. In some embodiments, the metal structure 170 is spaced apart from the insulation layer 140 by the etch stop layer 160. In some embodiments, the etch stop layer 160 and the insulation layer 140 are conformally disposed on the semiconductor layer 120a and spacer 130b. In some embodiments, the metal structure 170 includes a metal material, for example, titanium, and/or other suitable material(s), for example, titanium nitride. In some embodiments, the metal structure 170 covers a portion of a lateral surface 120 as of the semiconductor layer 120a. In some embodiments, the metal structure 170 extends from the semiconductor layer 120a to the spacer 130b along the line B-B′ shown in FIG. 1B.

In some embodiments, a dielectric layer 180 covers the substrate 100, the semiconductor layer 120a, and the metal structure 170. In some embodiments, the dielectric layer 180 is in contact with the semiconductor layer 120a, the spacer 130a, and the salicide structures 150al and 150a2. In some embodiments, the dielectric layer 180 is disposed on the etch stop layer 160 and the metal structure 170.

In some embodiments, the dielectric layer 180 includes silicon oxide, silicon nitride, silicon oxynitride, spin-on glass (SOG), fluorinated silica glass (FSG), carbon doped silicon oxide (e.g., SiCOH), BLACK DIAMOND® (Applied Materials of Santa Clara, Calif.), XEROGEL®, AEROGEL®, amorphous fluorinated carbon, Parylene, BCB (bis-benzocyclobutenes), FLARE®, SILK® (Dow Chemical, Midland, Mich.), polyimide, other proper porous polymeric materials, other suitable dielectric materials, and/or combinations thereof. In some embodiments, the dielectric layer 180 includes a high density plasma (HDP) dielectric material (e.g., HDP oxide) and/or a high aspect ratio process (HARP) dielectric material (e.g., HARP oxide). It is understood that the dielectric layer 180 may include one or more dielectric materials and/or one or more dielectric layers.

In some embodiments, contacts 190-1 and 190-2 are disposed on the region 100a. In some embodiments, the contact 190-1 is disposed on the salicide structure 150a1. In some embodiments, the contact 190-1 is electrically connected to the salicide structure 150al. In some embodiments, the contact 190-2 is disposed on the salicide structure 150a2. In some embodiments, the contact 190-2 is electrically connected to the salicide structure 150a2. In some embodiments, a capacitor contact 190-3 is disposed on the metal structure 170. In some embodiments, a bottom surface 190-1s of the contact 190-1 of the transistor 10 is lower than a bottom surface 190-3s of the capacitor contact 190-3 of the capacitor 12. In some embodiments, the capacitor contact 190-3 is electrically connected to the metal structure 170. In some embodiments, the capacitor contact 190-3 is spaced apart from the substrate 100.

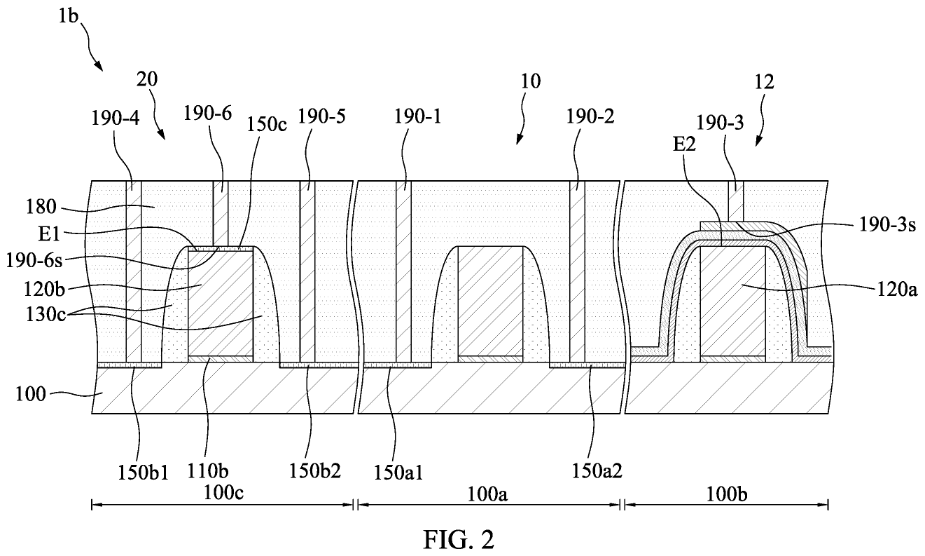

FIG. 2 illustrates a cross-sectional view of a semiconductor device 1b, in accordance with some embodiments of the present disclosure.

The difference between FIGS. 1C and 2 is that FIG. 2 further includes a device 20. In some embodiments, the semiconductor device 1b includes the semiconductor device 1a and the device 20. In some embodiments, the semiconductor device 1a includes a memory. In some embodiments, the semiconductor device 1a in FIG. 2 is the same as the semiconductor device 1a in FIG. 1C. In some embodiments, the device 20 is disposed on or within a region 100c of the substrate 100. The device 20 includes, for example, a logic device.

In some embodiments, a gate dielectric 110b is disposed on the region 100c. The material of the gate dielectric 110b is the same as or similar to that of the gate dielectric 110a.

In some embodiments, a semiconductor layer 120b is disposed on the gate dielectric 110b. In some embodiments, the semiconductor layer 120b is disposed on the region 100c of the substrate 100. In some embodiments, the semiconductor layer 120b is spaced apart from the semiconductor layer 120a. In some embodiments, the semiconductor layer 120b is also referred to as the “gate electrode 120b.” In some embodiments, the semiconductor layer 120b is spaced apart from the substrate 100 by the gate dielectric 110b. The material of the semiconductor layer 120b is the same as or similar to that of the semiconductor layer 120a.

In some embodiments, a spacer 130c is disposed on the region 100c. In some embodiments, the gate dielectric 110b and the semiconductor layer 120b are in contact with the spacer 130c.

In some embodiments, the spacer 130c is disposed on two opposite sides of the semiconductor layer 120b. The spacer 130c includes a single layer structure or a multilayer structure. In some embodiments, the spacer 130c includes SiO₂, SiN, SiCN, SiOCN, SiC, SiOC, SiON, or the like, or combinations thereof.

In some embodiments, salicide structures 150b1 and 150b2 are disposed in the region 100c. In some embodiments, the salicide structures 150b1 and 150b2 are spaced apart from the spacer 130c. In some embodiments, the salicide structures 150b1 and 150b2 are spaced apart from each other. The salicide structures 150b1 and 150b2 are located, for example, at two opposite sides of the semiconductor layer 120b. In some embodiments, a salicide structure 150c is disposed on the semiconductor layer 120b. In some embodiments, the salicide structure 150c is electrically connected to the semiconductor layer 120b. The salicide structures 150b1 and 150b2 are located with a region of the substrate 100 corresponding to source/drain regions. The salicide structures 150b1, 150b2, and 150c are also referred to as silicide structures.

In some embodiments, the semiconductor device 1b further includes contacts 190-4, 190-5, and 190-6. The contacts 190-4, 190-5, and 190-6 are disposed on the region 100c. In some embodiments, the contact 190-4 is disposed on the salicide structure 150b1. In some embodiments, the contact 190-5 is formed on the salicide structure 150b2. In some embodiments, the contact 190-6 is formed on the salicide structure 150c. In some embodiments, the contact 190-4 is electrically connected to the salicide structure 150b1. In some embodiments, the contact 190-5 is electrically connected to the salicide structure 150b2. In some embodiments, the contact 190-6 is electrically connected to the semiconductor layer 120b via the salicide structure 150c.

In some embodiments, the contacts 190-4, 190-5, and 190-6 are embedded in the dielectric layer 180. In some embodiments, the contacts 190-4 and 190-5 are disposed on opposite sides of the semiconductor layer 120b. In some embodiments, a lower surface 190-6s of the contact 190-6 is lower than a lower surface 190-3s of the capacitor contact 190-3. In some embodiments, an elevation E1 of the semiconductor layer 120b is substantially the same as an elevation E2 of the semiconductor layer 120a.

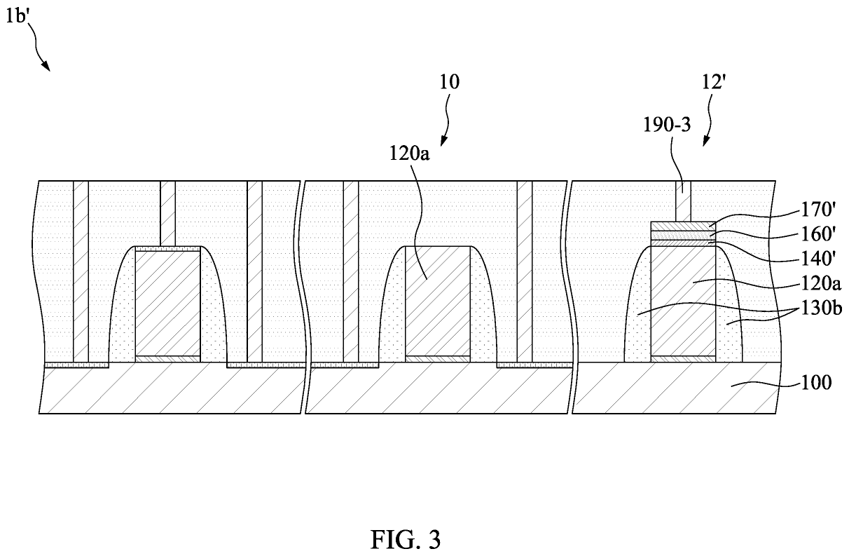

FIG. 3 illustrates a cross-sectional view of a semiconductor device 1b′, in accordance with some embodiments of the present disclosure.

The difference between the semiconductor device 1b of FIG. 2 and the semiconductor device 1b′ of FIG. 3 is that the semiconductor device 1b′ includes a capacitor 12′. The capacitor 12′ includes an insulation layer 140′, an etch stop layer 160′, and a metal structure 170′. The insulation layer 140′ is free from overlapping the spacer 130b. The width of the insulation layer 140′ is substantially the same as that of the semiconductor layer 120a. The etch stop layer 160′ is free from overlapping the spacer 130b. The metal structure 170′ is free from overlapping the spacer 130b. In some embodiments, the insulation layer 140′, the etch stop layer 160′, and the metal structure 170′ are absent on the spacer 130b. In some embodiments, the lateral surface of the semiconductor layer 120a is exposed from the insulation layer 140′. In some embodiments, the lateral surface of the semiconductor layer 120a is exposed from the etch stop layer 160′. In some embodiments, the lateral surface of the semiconductor layer 120a is exposed from the metal structure 170′.

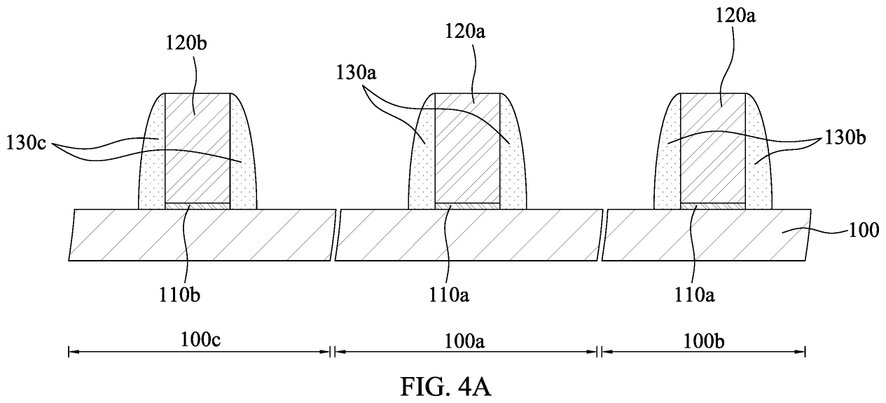

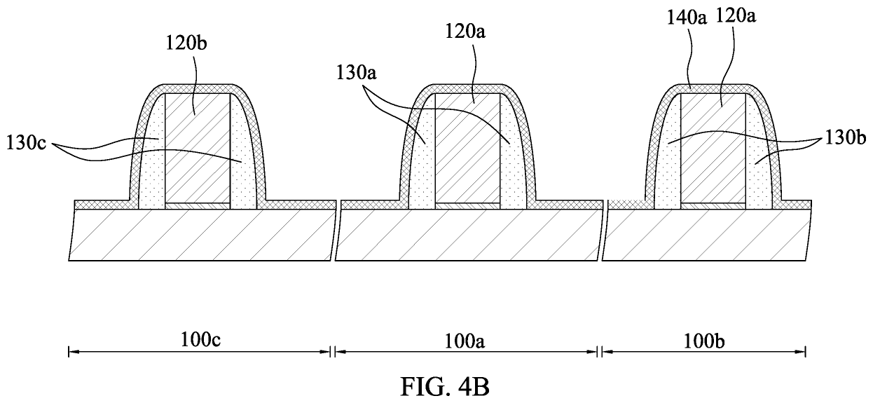

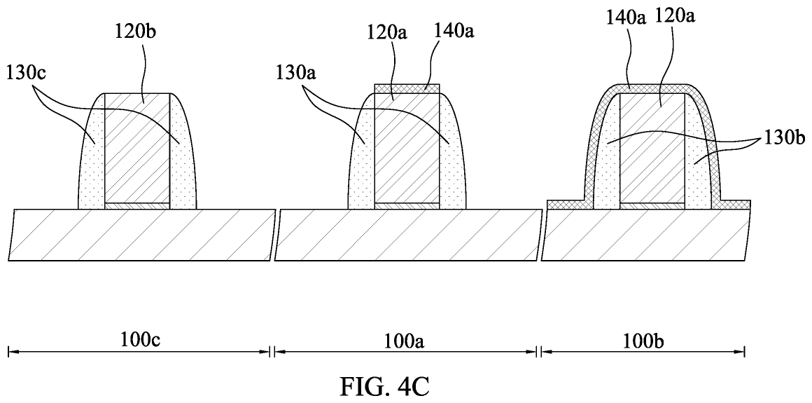

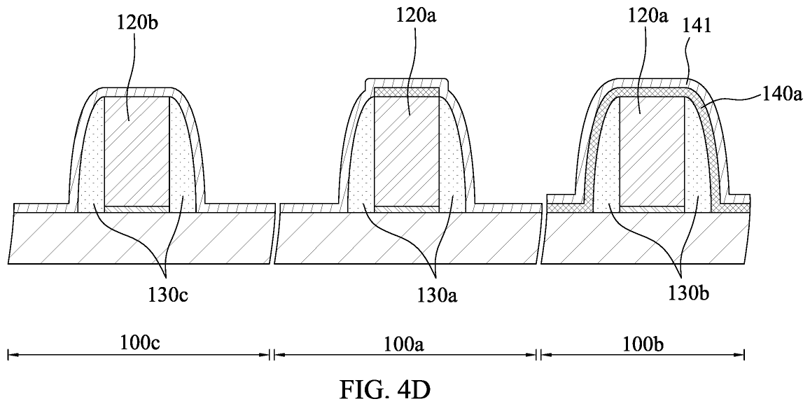

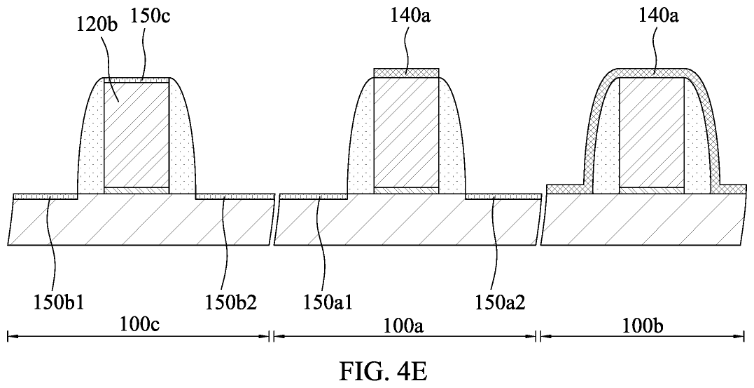

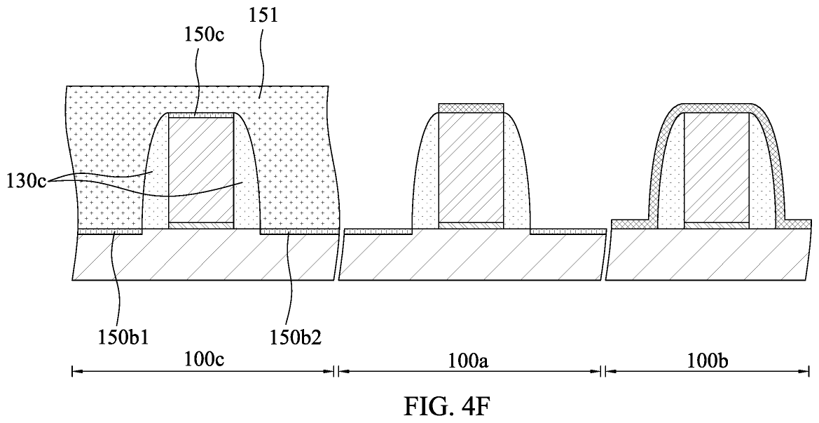

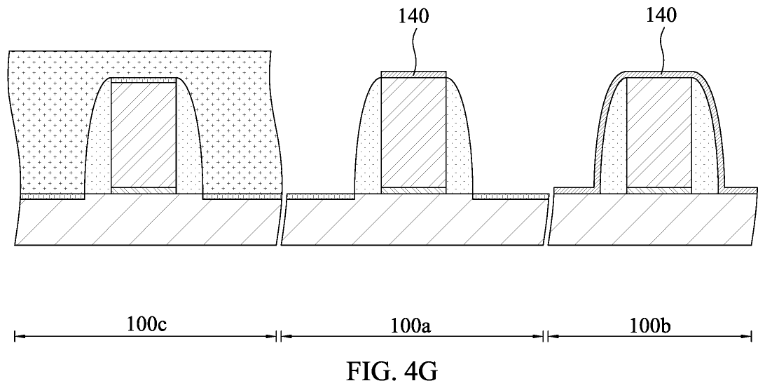

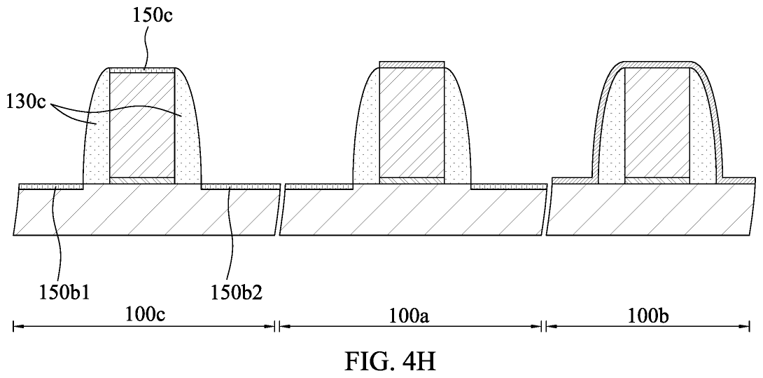

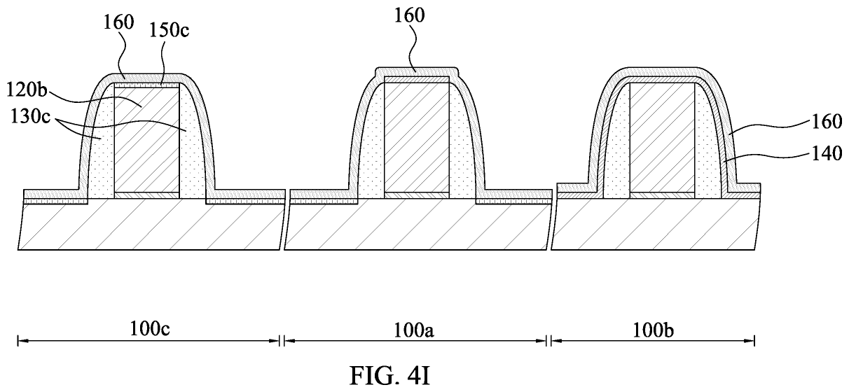

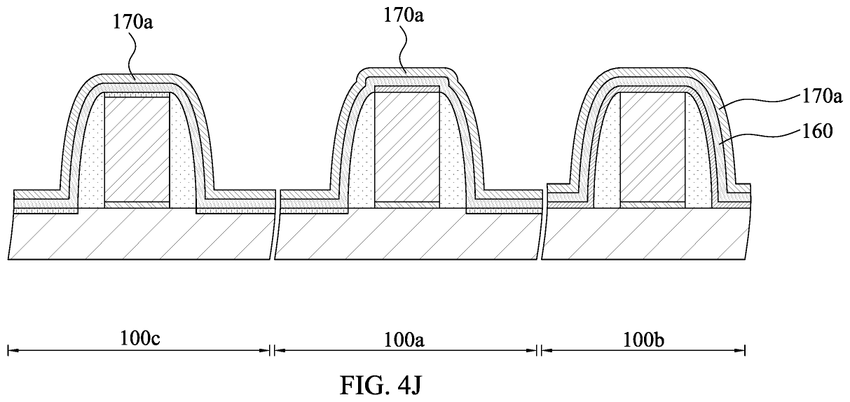

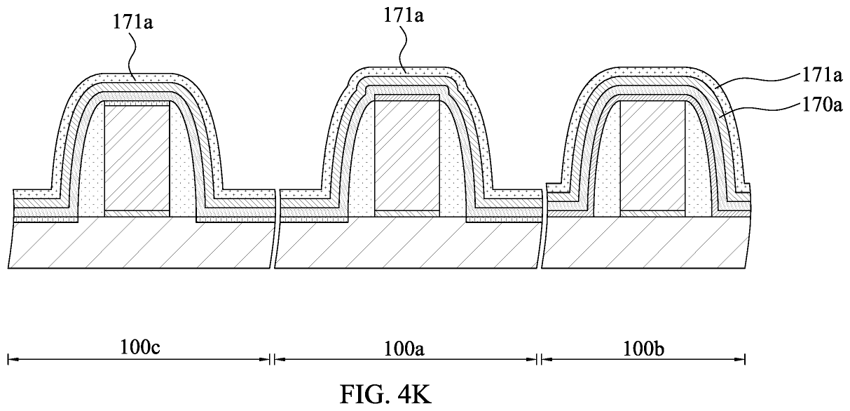

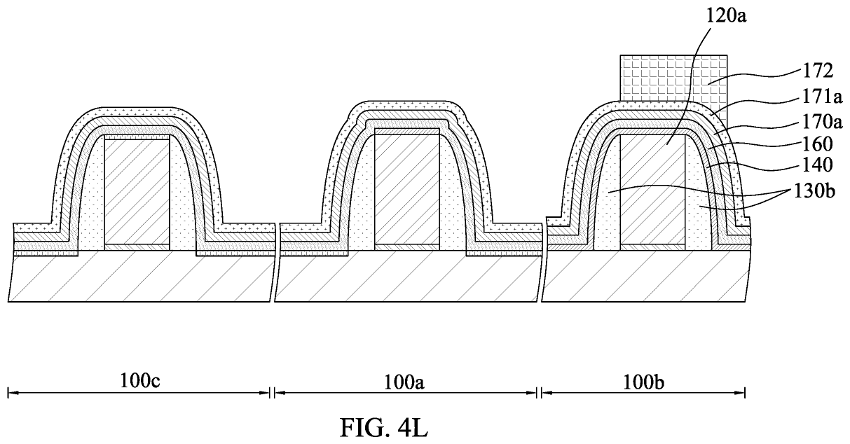

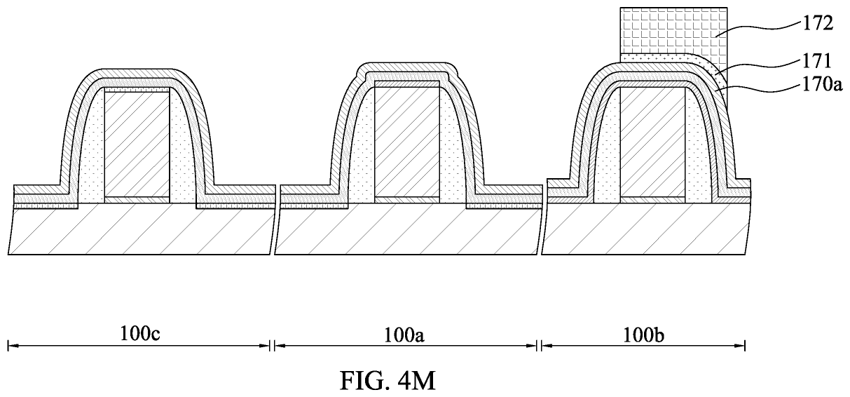

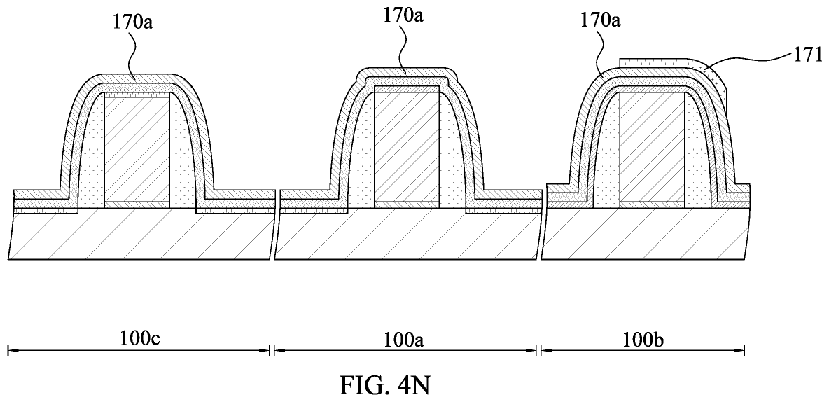

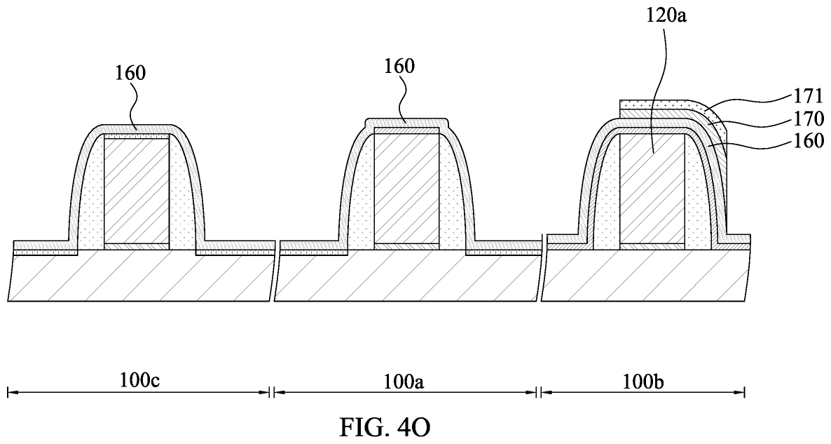

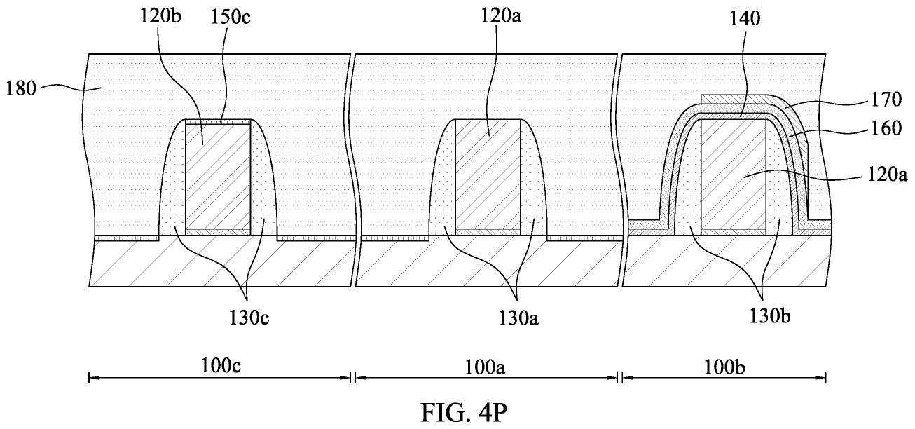

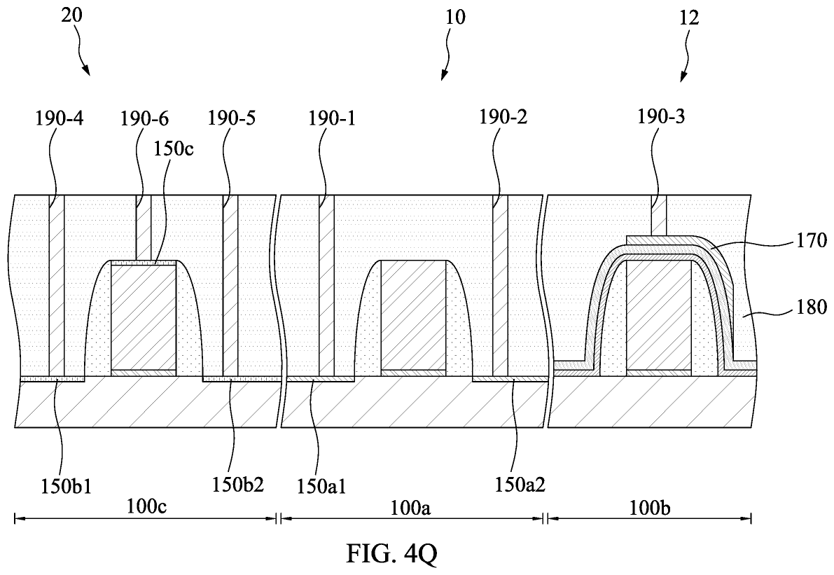

FIG. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, FIG. 4M, FIG. 4N, FIG. 4O, FIG. 4P, and FIG. 4Q illustrate various stages of manufacturing a semiconductor device 1b, in accordance with some embodiments of the present disclosure.

Referring to FIG. 4A, a substrate 100 is provided. The substrate 100 includes regions 100a, 100b, and 100c. A gate dielectric 110a is formed on the region 100a of a substrate 100. The gate dielectric 110a is formed on the region 100b of the substrate 100. A gate dielectric 110b is formed on the region 100c of the substrate 100. The gate dielectrics 110a and 110b may be formed by a deposition process (e.g., chemical vapor deposition (CVD), physical vapor deposition (PVD), atomic layer deposition (ALD), and/or other suitable process.

In some embodiment, a semiconductor layer 120a is formed on the gate dielectric 110a. A semiconductor layer 120b is formed on the gate dielectric 110b. The semiconductor layers 120a and 120b may be formed by a deposition process (e.g., CVD, PVD, and/or ALD). The material of the semiconductor layer 120a may be the same as or different from the semiconductor layer 120b. In other embodiments, the semiconductor layer 120a and 120b can be replaced by a metallic material, which function as a metal gate of a transistor.

In some embodiments, a spacer 130a is formed on the region 100a. A spacer 130b is formed on the region 100b. A spacer 130c is formed on the region 100c. The spacers 130a, 130b, and 130c are formed by a deposition process (e.g., CVD, PVD, and/or ALD).

Referring to FIG. 4B, an insulation layer 140a is formed to cover the semiconductor layers 120a and 120b. In some embodiments, the insulation layer 140a is formed on the regions 100a, 100b, and 100c. In some embodiments, the insulation layer 140a is formed on the spacers 130a, 130b, and 130c. The insulation layer 140a covers the spacers 130a, 130b, and 130c. The insulation layer 140a may be formed by a deposition process (e.g., chemical vapor deposition (CVD), physical vapor deposition (PVD), atomic layer deposition (ALD), and/or other suitable process. The material of the insulation layer 140a includes, for example, silicon oxide, silicon nitride, silicon oxynitride, or other suitable materials.

Referring to FIG. 4C, a portion of the insulation layer 140a is removed. The exposed portion by the insulation layer 140a is utilized to define a region on which a salicide structure is formed. The semiconductor layer 120b and the spacer 130c are exposed from the insulation layer 140a. In some embodiments, portions of the insulation layer 140a in the region 100a are removed. In some embodiments, the insulation layer 140a is removed by, for example, wet etching, dry etching, or other suitable processes.

Referring to FIG. 4D, a metal material 141 is conformally formed on the regions 100a, 100b, and 100c. The metal material 141 is in contact with the substrate 100, which is exposed by the insulation layer 140a. The metal material 141 is in contact with the upper surface of the semiconductor layer 120b. The metal material 141 may be formed by a deposition process (e.g., chemical vapor deposition (CVD), physical vapor deposition (PVD), atomic layer deposition (ALD), and/or other suitable process. In some embodiments, the metal material 141 includes titanium, cobalt, nickel, or other suitable materials.

Referring to FIG. 4E, the structure shown in FIG. 4D is annealed. Salicide structures 150a1 and 150a2 are formed in the region 100a. Salicide structures 150b1 and 150b2 are formed in the region 100c. A salicide structure 150c is formed on the top of the semiconductor layer 120b. After the salicide structure 150a1, 150a2, 150b1, 150b2, and 150c are formed, the metal material 141 is removed. As a result, the insulation layer 140a, and the regions 100a and 100c of the substrate 100 are exposed.

Referring to FIG. 4F, a photoresist material 151 is formed on a portion of the region 100c. The photoresist material 151 covers the spacer 130c, the salicide structure 150c, and the salicide structures 150b1 and 150b2. In some embodiments, the photoresist material 151 may be formed by spin coating and/or other suitable process.

Referring to FIG. 4G, the insulation layer 140a is thinned to form an insulation layer 140. In some embodiments, the insulation layer 140 is thinner than the insulation layer 140a in FIG. 4E.

Referring to FIG. 4H, the photoresist material 151 is removed from the region 100c. In some embodiments, the salicide structures 150b1, 150b2, 150c and the spacer 130c are exposed.

Referring to FIG. 4I, an etch stop layer 160 is conformally formed on the region 100a, 100b, and 100c. The etch stop layer 160 covers the insulation layer 140. The etch stop layer 160 covers the semiconductor layer 120b and the regions 100a and 100c. In some embodiments, the etch stop layer 160 may have a higher resistance to an etchant in comparison with other materials such as a metal or alloy. In some embodiments, the etch stop layer 160 may include silicon nitride, silicon oxynitride, silicon carbide, or other suitable materials.

Referring to FIG. 4J, a conductive layer 170a is conformally formed on the regions 100a, 100b, and 100c. The conductive layer 170a is conformally formed on the etch stop layer 160. In some embodiments, the conductive layer 170a is formed by a deposition process (e.g., chemical vapor deposition (CVD), physical vapor deposition (PVD), atomic layer deposition (ALD), and/or other suitable process. In some embodiments, the conductive layer 170a includes metal materials.

Referring to FIG. 4K, a mask layer 171a is conformally formed on the conductive layer 170a. In some embodiments, the mask layer 171a is configured to define a pattern or a profile of the conductive layer 170a in subsequent stages. In some embodiments, the mask layer 171a may include silicon nitride, silicon oxynitride, silicon carbide, or other suitable materials.

Referring to FIG. 4L, a photoresist material 172 is formed on the region 100c. The regions 100a and 100b are exposed from the photoresist material 172. The photoresist material 172 is formed on the mask layer 171a in the region 100c. The photoresist material 172 covers a portion of the mask layer 171a. In some embodiments, the photoresist material 172 laterally covers the semiconductor layer 120a, one side of the spacer 130b, a portion of the insulation layer 140, a portion of the etch stop layer 160, and a portion of the conductive layer 170a.

Referring to FIG. 4M, portions, exposed by the photoresist material 172, of the mask layer 171a are removed. The remaining mask layer 171a forms a mask structure 171 on the conductive layer 170a. The regions 100a and 100c are exposed from the mask structure 171.

Referring to FIG. 4N, the photoresist material 172 is removed. As shown in FIG. 4N, the mask structure 171 is exposed, and portions of the conductive layer 170a is exposed from the mask structure 171.

Referring to FIG. 4O, portions, exposed from the mask structure 171, of the conductive layer 170a are removed. The etch stop layer 160, not covered by the mask structure 171, is exposed. The remaining conductive layer 170a forms a metal structure 170 on the etch stop layer 160. In some embodiments, the conductive layer 170a is patterned to form the metal structure 170 covering the semiconductor layer 120a. In some embodiments, the conductive layer 170a is removed by, for example, wet etching, dry etching, or other suitable processes.

Referring to FIG. 4P, the mask structure 171 is removed. The etch stop layer 160 in the regions 100a and 100c is removed. The insulation layer 140 in the region 100a is removed. A dielectric layer 180 is formed on the regions 100a, 100b, and 100c. The dielectric layer 180 covers the semiconductor layers 120a and 120b. In some embodiments, the dielectric layer 180 is formed by, for example, CVD, PVD, spin coating, and/or other suitable processes. In other embodiments, the etch stop layer 160 remains on the regions 100a and 100c. In other embodiments, the insulation layer 140 remains on the region 100a.

Referring to FIG. 4Q, contacts 190-1, 190-2, 190-4, 190-5, and 190-6 are formed, and a capacitor contact 190-3 is formed on the metal structure 170. The contacts 190-1 and 190-2 are formed on the region 100a. The region 100a and the structures formed thereon form the transistor 10 as shown in FIG. 2. The contact capacitor contact 190-3 is formed on the region 100b. The region 100b and the structures formed thereon form the capacitor 12 as shown in FIG. 2. The contacts 190-4, 190-5, and 190-6 are formed on the region 100c. The region 100c and the structures formed thereon form the device 20 as shown in FIG. 2. As a result, a semiconductor device, such as the semiconductor device 1b as shown in FIG. 2, is produced. In this embodiment, the memory device can be integrated within a process for forming a logic device. Further, said memory device reduces the size. Therefore, the performance of the semiconductor device is enhanced.

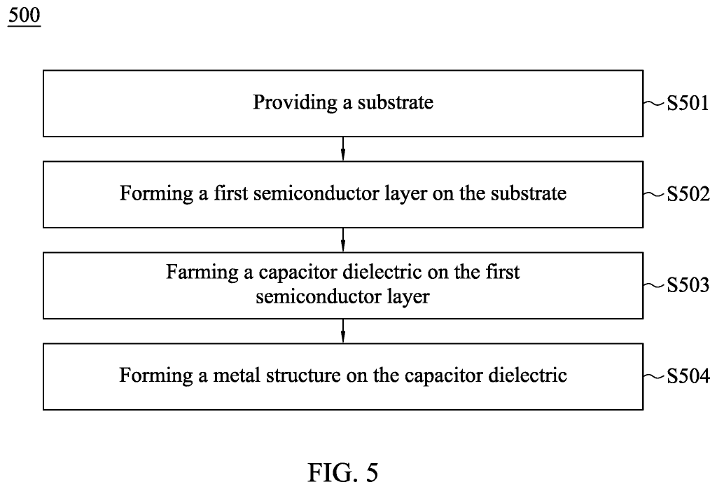

FIG. 5 is a flow chart illustrating a method for manufacturing a semiconductor device, in accordance with various aspects of the present disclosure.

The method 500 begins with operation S501 in which a substrate is provided.

The method 500 continues with operation S502 in which a first semiconductor layer is formed on the substrate. For example, the operation S502 can include forming the semiconductor layer 120a on the substrate 100 as shown in FIGS. 1C, 2 and 3.

The method 500 continues with operation S503 in which a capacitor dielectric is formed on the first semiconductor layer. For example, the operation S503 can include forming the insulation layer 140 on the semiconductor layer 120a as shown in FIGS. 1C and 2.

The method 500 continues with operation S504 in which a metal structure is formed on the capacitor dielectric. For example, the operation S504 can include forming the metal structure 170 on the insulation layer 140 as shown in FIGS. 1C and 2.

The method 500 is merely an example, and is not intended to limit the present disclosure beyond what is explicitly recited in the claims. Additional operations can be provided before, during, and after the method 500, and some operations described can be replaced, eliminated, or moved around for additional embodiments of the method.

Some embodiments of the present disclosure provide a semiconductor device. The semiconductor device includes a substrate, a transistor, and a capacitor. The transistor comprises a gate electrode disposed on the substrate. The capacitor is electrically connected to the transistor and comprising a capacitor dielectric and a capacitor electrode. The capacitor dielectric and the capacitor electrode are stacked over the gate electrode of the transistor.

Some embodiments of the present disclosure provide a semiconductor device. The semiconductor device includes a substrate, a first gate dielectric, a first semiconductor layer, an insulation layer, and a metal structure. The first gate dielectric is disposed on the substrate. The first semiconductor layer is disposed on the first gate dielectric. The insulation layer is disposed on the first semiconductor layer. The metal structure is disposed on the insulation layer. The first semiconductor layer functions as a first electrode of a capacitor, and the metal structure function as a second electrode of the capacitor.

Some embodiments of the present disclosure provide a method of manufacturing a semiconductor device. The method includes: providing a substrate, forming a first semiconductor layer on the substrate, forming a capacitor dielectric on the first semiconductor layer, and forming a metal structure on the capacitor dielectric, wherein the first semiconductor layer functions as a first electrode of a capacitor, and the metal structure function as a second electrode of the capacitor.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a transistor comprising a gate electrode disposed on the substrate; and
a capacitor electrically connected to the transistor and comprising a capacitor dielectric and a capacitor electrode,
wherein the capacitor dielectric and the capacitor electrode are stacked over the gate electrode of the transistor.

2. The semiconductor device of claim 1, wherein the capacitor electrode vertically overlaps the gate electrode of the transistor.

3. The semiconductor device of claim 1, wherein the gate electrode of the transistor is electrically floating.

4. The semiconductor device of claim 1, further comprising:
a capacitor contact disposed on the capacitor electrode.

5. The semiconductor device of claim 1, wherein the capacitor dielectric is spaced apart from the substrate.

6. The semiconductor device of claim 1, further comprising:
a spacer disposed on a sidewall of the gate electrode of the transistor,
wherein the capacitor electrode is disposed on the spacer.

7. The semiconductor device of claim 6, wherein the capacitor electrode is conformally disposed on the spacer.

8. The semiconductor device of claim 6, wherein the transistor comprises a first contact and a second contact arranged along a first orientation, and the capacitor electrode extends from the gate electrode to the spacer along a second orientation different from the first orientation.

9. The semiconductor device of claim 1, wherein the transistor comprises a first contact and a second contact arranged along a first orientation, and the capacitor comprises a capacitor contact disposed between the first contact and the second contact along a second orientation.

10. A semiconductor device, comprising:
a substrate;
a first gate dielectric disposed on the substrate;
a first semiconductor layer disposed on the first gate dielectric;
an insulation layer disposed on the first semiconductor layer; and
a metal structure disposed on the insulation layer,
wherein the first semiconductor layer functions as a first electrode of a capacitor, and the metal structure function as a second electrode of the capacitor.

11. The semiconductor device of claim 10, further comprising:
a capacitor contact electrically connected to the second electrode of the capacitor and spaced apart from the substrate.

12. The semiconductor device of claim 11, further comprising:
a second semiconductor layer disposed on the substrate and spaced apart from the first semiconductor layer; and
a contact electrically connected to the second semiconductor layer, wherein a lower surface of the contact is lower than a lower surface of the capacitor contact.

13. The semiconductor device of claim 11, wherein an elevation of the second semiconductor layer is substantially the same as an elevation of the first electrode of the capacitor.

14. The semiconductor device of claim 11, wherein the capacitor contact is in contact with the second electrode of the capacitor.

15. The semiconductor device of claim 10, wherein a width of the metal structure exceeds a width of the first semiconductor layer along an X-axis.

16. The semiconductor device of claim 10, wherein a portion of the first semiconductor layer is exposed from the metal structure.

17. The semiconductor device of claim 10, wherein the metal structure covers a portion of a lateral surface of the first semiconductor layer.

18. A method for manufacturing a semiconductor device, comprising:
providing a substrate;
forming a first semiconductor layer on the substrate;
forming a capacitor dielectric on the first semiconductor layer; and
forming a metal structure on the capacitor dielectric,
wherein the first semiconductor layer functions as a first electrode of a capacitor, and the metal structure function as a second electrode of the capacitor.

19. The method of claim 18, wherein forming the metal structure comprises:
forming a conductive layer on the capacitor dielectric; and
patterning the conductive layer to form the metal structure covering the first semiconductor layer.

20. The method of claim 18, further comprising:
forming a second semiconductor layer on the substrate forming an insulation layer to cover the first semiconductor layer and the second semiconductor layer;
removing a portion of the insulation layer over the second semiconductor layer to form the capacitor dielectric covering the first semiconductor layer; and
forming a salicide layer on the second semiconductor layer.
